(19) United States
(12) Patent Application Publication
(10) Pub. No.: US 2025/0063273 A1
(43) Pub. Date: Feb. 20, 2025

(54) ELECTRONIC DEVICE

(71) Applicant: PanelSemi Corporation, New Taipei City (TW)

(72) Inventor: Yu-Kai LIN, New Taipei City (TW)

(21) Appl. No.: 18/805,820

(22) Filed: Aug. 15, 2024

Related U.S. Application Data
(60) Provisional application No. 63/519,700, filed on Aug. 15, 2023.

(51) Int. Cl. H04N 25/78; G09G 3/32; H03K 17/56; H04N 25/30

(52) U.S. Cl. CPC H04N 25/78; G09G 3/32; H03K 17/56; H04N 25/30; G09G 2330/021; G09G 2370/00

(57) ABSTRACT

An electronic device, including a substrate. The substrate includes a plurality of driver units converting a data signal into a driving signal, a plurality of functional elements driven by the driver units, and a plurality of switches coupling to the driver units and the functional elements. The switch is enabled via a prompt signal to activate the driving signal to the functional elements. The driving signal is transmitted from the driver unit to the functional element by switches enabling.

### CROSS REFERENCE TO RELATED APPLICATIONS

This Non-provisional application which claims priority under 35 U.S.C. § 119(a) on Patent Application No(s). 63/519,700 filed in United States of America on Aug. 15, 2023, the entire contents of which are hereby incorporated by reference.

### BACKGROUND

### Technology Field

The disclosure relates to an electronic device, especially to an electronic device that utilizes advanced circuitry design for efficient signal propagation and component operation.

### Description of Related Art

For large electronic devices having plural components, it would take a lot of energy to control these components separately. In addition, in order to accurately control these components, a lot of control units, such as integrated circuits, are also required. It will need more spaces for arranging these components, and the manufacturing cost of the large electronic device will be higher. Therefore, improving control accuracy and efficiency to the components and signal transmission of the large electronic device is an important improvement subject.

### SUMMARY

One or more exemplary embodiments of this disclosure are to provide an electronic device.

An electronic device comprising a substrate is disclosed, the substrate includes a plurality of driver units, a plurality of functional elements, and a plurality of switches. The driver units receive one or ones of data signals and convert corresponding one or ones of the data signals into one or ones of driving signals. The functional elements are driven by the corresponding one or ones of the driver units. The switches are coupled to the driver units and the functional elements, and one or ones of the switches are enabled via one or ones prompt signal to activate one or ones of the driving signals to a corresponding one or ones of the functional elements. The driving signals are transmitted from one or ones of the driver units to the functional elements by corresponding one or ones of the switches enabling.

In one embodiment, the substrate further defines a plurality of circuitries which receive the data signals. One of the driver units, one or ones of the functional elements, and one or ones of the switches are provided in a corresponding circuitry.

In one embodiment, the driver units receive the data signals sequentially within a timeframe.

In one embodiment, the driving signals are transmitted from one or ones of the driver units to the corresponding ones of the functional elements within a sub-timeframe, in which the sub-timeframe is broken from the timeframe.

In one embodiment, ones of the driver units are components individually from the substrate and are arranged on the substrate.

In one embodiment, either or both of at least one of the driver units and at least one of the switches is a semiconductor integrated circuit (IC).

Ine one embodiment, the switch is integrated within the substrate or integrated with a corresponding one of the functional elements.

In one embodiment, at least one of the switches include a thin film transistor, or at least one of the switches is a thin film transistor.

In one embodiment, at least one of the switches includes a carrier, and the thin film transistor thereof is formed on the carrier.

In one embodiment, the functional elements are self-emitting element, such as light-emitting diode (LED s) or organic LEDs (OLEDs).

In one embodiment, the substrate defines at least one active area; the driver units, the functional elements, and the switches are arranged within the at least one active area.

In one embodiment, the functional elements are grouped, and one or ones groups of the grouped functional elements can be driven by the corresponding one or ones of the driver units; the switches are also grouped, and one or ones groups of the grouped switches correspond to one or ones groups of the grouped functional elements; wherein one or ones of the driver units defines one or more outputs corresponding to one or ones groups of the grouped functional elements.

In one embodiment, the switch is arranged between the corresponding one of the driver units and the corresponding one or ones of the functional elements.

In one embodiment, the switch is arranged between the corresponding one of the driver units and the corresponding one of the functional elements.

In one embodiment, the functional element is arranged between the corresponding one of the driver units and the corresponding one of the switches.

In one embodiment, one of the switches transmit the driving signals from a corresponding driver unit to the corresponding ones of the functional units.

In one embodiment, the functional elements are grouped, and one or ones groups of the grouped functional elements is driven by a corresponding one or ones of the driver units; the switches are also grouped, and one or ones groups of the grouped switches corresponds to one or ones groups of the grouped functional elements; one group of the switches activates one or ones of the driving signal from a corresponding one or ones of the driver units to serve one or ones groups of the grouped functional elements.

In one embodiment, one switch is coupled to one driver unit and one functional element.

In one embodiment, the driving signal delivered by the driver unit is current typed.

In one embodiment, the driver units are electrically connected in serial, and a later one of the driver units is driven by a previous one of the driver units.

In one embodiment, the substrate further includes a plurality of first lines respectively conveying a plurality of scan signals, wherein the driver units interface the first lines respectively, and one of the scan signals is introduced from a corresponding one of the first lines to the driver unit.

In one embodiment, the substrate further includes a plurality of second lines respectively conveying a plurality of data signals, and a plurality of controlling lines respectively conveying the prompt signals; wherein the driver units are coupled to the second lines and the controlling lines respectively.

In one embodiment, the substrate further includes a plurality of traces formed on the substrate and serving the connection to the driver unit, the switches and the functional elements respectively, and the traces are thin filmed traces which can be manufactured by thin-film process.

In one embodiment, the electronic device further includes a system driver coupled with the substrate and delivers the plurality of data signals.

In one embodiment, one or ones of the driver units and one or ones of the functional elements are arranged on opposite surface of the substrate, and the projections perpendicular to the substrate of both are least partially overlapped.

In one embodiment, one or ones of the driver units and one or ones of the functional elements are arranged on one same surface of the substrate.

An electronic device comprising a substrate is also disclosed in which the substrate includes a plurality of pixel control units, a plurality of functional elements, and a plurality of switches. The pixel control units receive one or ones of sensing signals and converts corresponding one or ones of the sensing signals into one or ones of readout signals. The functional elements are configured to one or ones of the pixel control units. The switches are coupled to the pixel control units and the functional elements, and one or ones of the switches are enabled via one or ones prompt signals to activate one or ones of the sensing signals from corresponding one or ones of the functional element, one or ones of the sensing signals are transmitted from one or ones of the functional elements to one or ones of the pixel control units by the corresponding switches enabling.

In one embodiment, the substrate further defines a plurality of circuitries receiving a plurality of sensing signals; at least one of the pixel control units, ones of the functional elements, and ones of the switches are provided in one corresponding circuitry.

In one embodiment, the pixel control units deliver the readout signals sequentially within a timeframe.

In one embodiment, the sensing signals are transmitted to the pixel control units from the corresponding functional elements within a sub-timeframe in which the sub-timeframe is broken down from the timeframe.

In one embodiment, the pixel control units is a component individual from and disposed on the substrate.

In one embodiment, either or both of the pixel control unit and the switch is a semiconductor IC.

In one embodiment, one or ones of the switches are integrated within the substrate, a corresponding one of the functional elements or a corresponding one of the pixel control units.

In one embodiment, at least one or ones of the switches includes a thin film transistor or at least one of the switches is a thin film transistor.

In one embodiment, one or ones of the switches includes a carrier, and the thin film transistor thereof is formed on the carrier.

In one embodiment, one or ones of the functional elements are photo sensors or ultrasonic transducers.

In one embodiment, the substrate defines at least one active area; and the pixel control units, the functional elements, and the switches are arranged within the at least one active area.

In one embodiment, the functional elements are grouped, and the switches are grouped, and one or ones groups of the grouped switches relates to corresponding one or ones of the grouped functional elements; one or ones of the pixel control units defines one or more inputs corresponding to and receiving sensing signals form one or ones groups of the grouped functional elements.

In one embodiment, the switch is arranged between one corresponding pixel control unit and one corresponding functional unit.

In one embodiment, the functional element is arranged between one corresponding pixel control unit and one corresponding switch.

In one embodiment, one or ones of the switches activates one or ones of the sensing signals from one or ones of the functional elements to a corresponding one or ones of the pixel control units.

In one embodiment, the pixel control units are grouped, and one or ones groups of the grouped pixel control units relates to corresponding one or ones of the functional elements; one or ones groups of the grouped pixel control units receives one or ones of the sensing signals from one or ones of the functional elements by the corresponding one or ones of the switches enabling.

In one embodiment, the sensing signals received by the pixel control units are current typed, voltage typed or charge typed.

In one embodiment, the pixel control units are electrically connected in serial, and a later one of the pixel control units is informed to deliver one of the readout signals by a previous one of the pixel control units.

In one embodiment, the substrate further includes a plurality of first lines respectively conveying a plurality of first signals; the pixel control units coupled to the first lines respectively, and one of the first signals are introduced from a corresponding one of the first lines to one or ones of the pixel control unit.

In one embodiment, the substrate further includes a plurality of second lines and a plurality of controlling lines for respectively conveying the sensing signals and the prompt signals; and the pixel control units are coupled to the second lines and the controlling lines.

In one embodiment, one pixel control unit is coupled to one second line and one controlling line.

In one embodiment, the substrate further includes a plurality of traces formed on the substrate and for the connection of the pixel control units, the switches, and the functional elements respectively, and the traces are thin-filmed which can be manufactured by thin-film process.

In one embodiment, the electronic device further includes a system driver coupled with the substrate and receives the readout signals.

In one embodiment, the one or ones of the pixel control units and one or ones of the functional elements are arranged on opposite surfaces of the substrate, and the projections perpendicular to the substrate of both are least partially overlapped.

In one embodiment, one or ones of the pixel control units and one or ones of the functional elements are arranged on one same surface of the substrate.

In one embodiment, one or ones of the pixel control units include an analog-to-digital converting circuit, and the sensing signals are transformed from an analog form to a digital form through the analog-to-digital converting circuit.

Accordingly, this disclosure provides an electronic device employing a unique configuration of plural driver units (ex. Driver ICs), functional elements (ex. LEDs) paired with driver units, and switches on/in a substrate, in which the functional elements cab be grouped. The driver units receive a plurality of data signals and convert them into a plurality of driving signals, and the driving signals are transmitted sequentially to the corresponding functional elements through enabled switches.

This disclosure also provides an electronic device employing a unique configuration of plural pixel control units, plural functional elements, and plural switches on/in a substrate. The pixel control unit receives multiple sensing signals within a timeframe and transforms the sensing signals into corresponding readout signals. Ones of the functional elements relates to one or ones pixel control units. The switches are connected to the pixel control units and the functional elements, and the switches are activated by a prompt signal to initiate one of the sensing signals from a corresponding functional element to the addressed pixel control unit. The sensing signals are sequentially transmitted from the functional elements to the corresponding pixel control unit by activating switches.

### BRIEF DESCRIPTION OF THE DRAWINGS

FIG. 1A is a circuit diagram of one embodiment of the present invention;

FIG. 1B is a schematic diagram showing the signal transduction of the present invention;

FIG. 1C is a circuit diagram of another embodiment of the present invention;

FIG. 1D is a circuit diagram of another embodiment of the present invention;

FIG. 2 is a circuit diagram of one embodiment of the present invention;

FIG. 3 is a circuit diagram of one embodiment of the present invention;

FIG. 4 is a circuit diagram of one embodiment of the present invention; and

FIG. 5 is a circuit diagram of one embodiment of the present invention.

### DETAILED DESCRIPTION OF THE DISCLOSURE

The disclosure will become more fully understood from the detailed description and accompanying drawings, which are given for illustration only, and thus are not limitative of the present disclosure.

The present disclosure will be apparent from the following detailed description, which proceeds with reference to the accompanying drawings, wherein the same references relate to the same elements.

This disclosure provides an electronic device including a substrate, and the substrate comprises a plurality of driver units, a plurality of switches and a plurality of functional elements. The plurality of the functional elements are configured to one or ones of the driver units respectively. The switch is coupled with the driver unit and the functional elements. The driver unit receives one or ones of data signals and converts the data signal to one or ones of driving signals. The switch is enabled by a prompt signal, then the switch activates a corresponding one driving signal to drive a corresponding functional element.

This disclosure also provides an electronic device including a substrate, and the substrate comprises a plurality of pixel control units, a plurality of switches and a plurality of functional elements. The switch is coupled with the pixel control unit and the functional elements. The pixel control unit receives a sensing signal from the functional element.

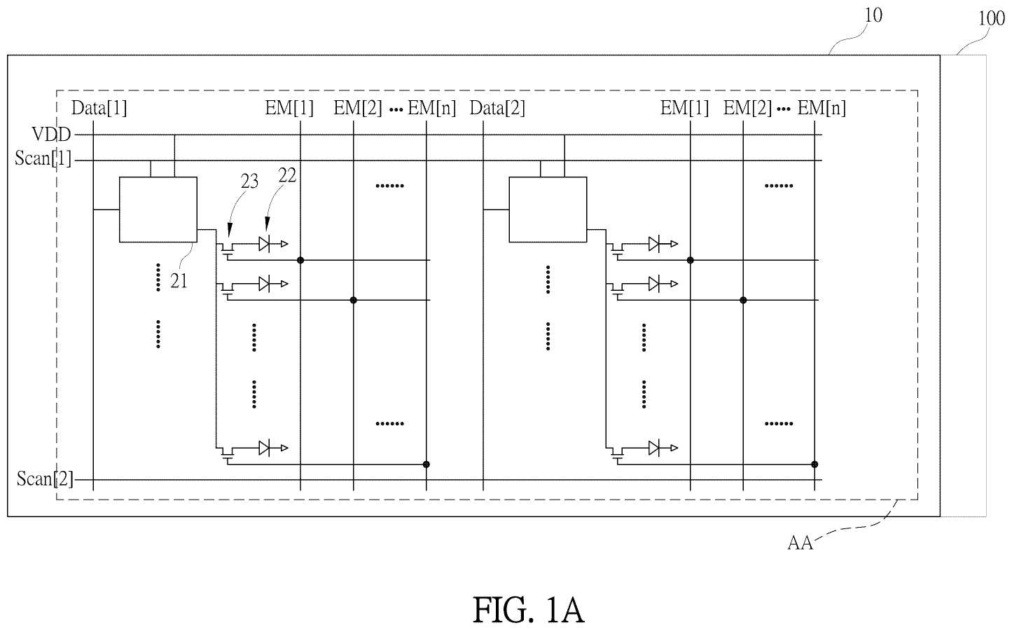

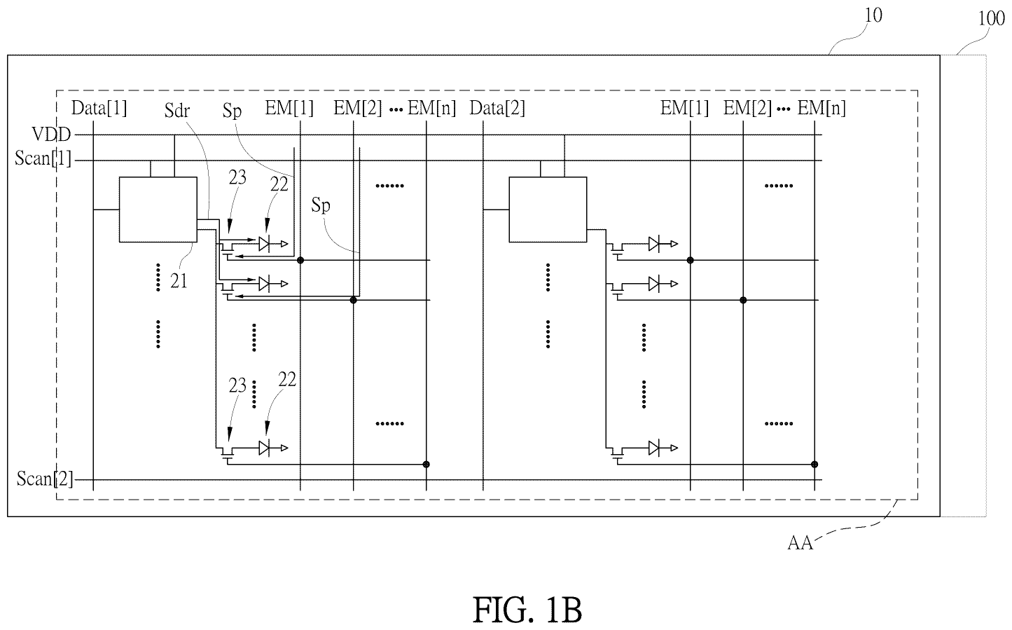

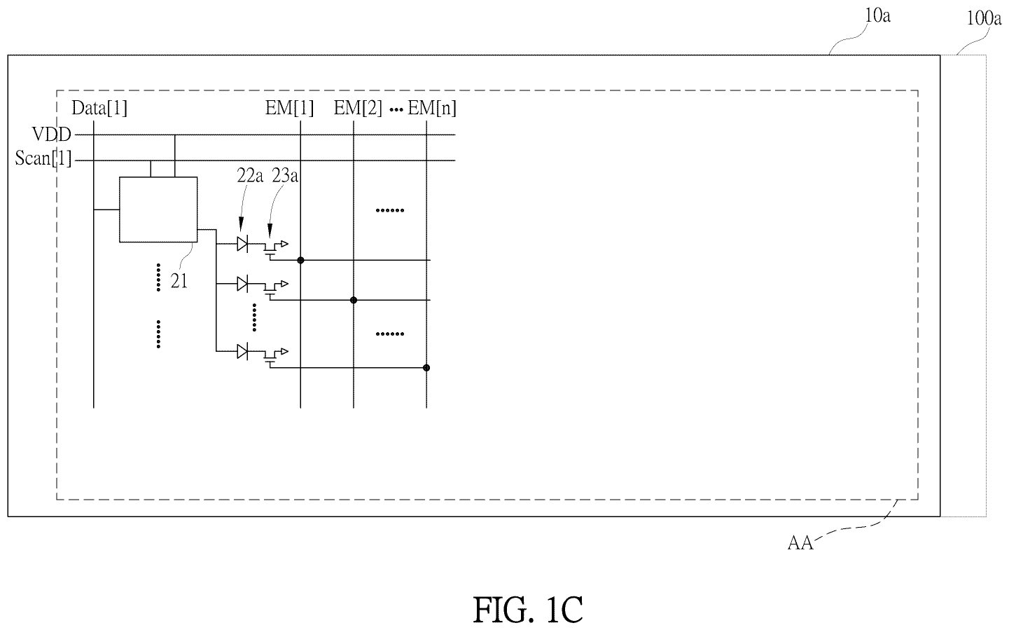

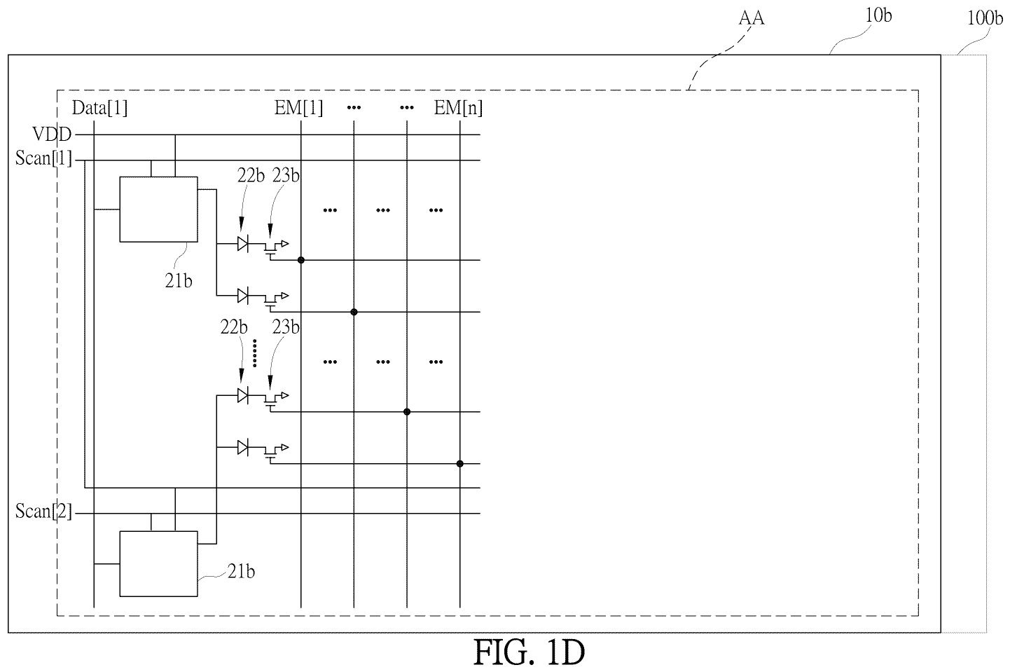

This disclosure can be applied to a display device as shown in FIG. 1A to FIG. 4 but this embodiment does not intend to limit the scope of the present invention. FIG. 1A shows an electronic device 100, the electronic device 100 includes a substrate 10, the substrate 10 contains a plurality of driver units 21, a plurality of functional elements 22, and a plurality of switches23. One or ones of the driver units 21 receive a plurality of data signals and convert corresponding ones of the data signals into a plurality of driving signals, in this case, the data signal can be delivered from the data line to the driver unit 21. The functional elements 22 are configured to one or ones of the driver units 21 respectively. The switches 23 are coupled with the driver units 21 and the functional elements 22. In FIG. 1A, one driver unit 21 is coupled with plural switches 21 and plural functional elements 22, in which the switches 21 and the functional elements 22 are arranged on one-on-one manner.

Referring to FIG. 1B, after the data signal is converted to the driving signal by the driver unit 21, the switch 23 is enabled via a corresponding prompt signal Sp, and in this case, the prompt signal Sp is delivered from the emission line EM. Then, the switch activates the corresponding driving signal Sd to drive the corresponding functional element 22. In this case, the switch 23 is arranged between the driver unit 21 and the functional element 22. In another case, the functional element 22a/22b of the electronic device 100a/100b can be arranged between the between the switch 23a/23b and the driver unit 21a/21b as shown in FIG. 1C or 1D.

Referring to FIG. 1B, the data signals Sda are sequentially transmitted to the driver unit 21 within a timeframe in some cases. In addition, the driving signals Sdr from the driver unit 21 are transmitted to the corresponding ones of the functional elements 23 within a sub-timeframe, in which the sub-timeframe is broken from the time frame. The driving signal Sdr delivered by the driver unit 21 can be current typed, but not limited thereto.

In some cases, the substrate 10 further defines a plurality of circuitries (not illustrated), and the circuitries receive a plurality of data signals within the timeframe; wherein one driver unit, one or ones of the functional elements, one or ones of the switches are provided in one corresponding circuitry. The circuitries can be arranged individually as referred in FIG. 1A/1B, or can be staggered alternately or arbitrary as referred in FIG. 1D.

In FIG. 1B, the electronic device 100 includes a plurality of first lines (signed as “Scan[n]” in FIG. 1B in which “n” is an integer) respectively conveying a plurality of scan signals. The driver units 21 are respectively coupled with the first lines, and one of the scan signals is introduced from a corresponding one of the first lines. In this case, the electronic device 100 further includes a plurality of second lines (signed as “Data[n]” in FIG. 1B in which “n” is an integer) respectively conveying a plurality of data signals. The electronic device 100 also includes a plurality of controlling lines (signed as “EM[n]” in FIG. 1B in which “n” is an integer) respectively conveying the prompt signals. The circuitries are arranged between one or ones of the second lines and the controlling lines.

In some cases, the functional elements 22 are grouped, and one or ones groups of the grouped functional elements 22 are driven by a one corresponding driver unit 21.

In other cases, the functional elements 22 are grouped, and the switches 23 are also grouped. At least one group of the grouped switches 23 corresponds to one or ones groups of the grouped functional elements 22. The driving signals are transmitted sequentially from one driver unit 21 to the corresponding one or more groups of the grouped functional elements 22 by the corresponding one or more groups of the grouped switches 23 enabling.

To be noted, in one or ones groups of the grouped functional elements 22, the driving signals are transmitted sequentially from the driver unit 21 by the corresponding switch(es) 23 enabling. Then, the functional element 23 operates according to its corresponding driving signal received. To be noted, the driver unit 21 is considered as a pixel control unit, which is an integrated circuit (IC). The driver unit 21 can be a semiconductor IC further scaled under mini meter, such as mini-IC, micro-IC, or the like.

In some cases, the driver units 21 receive the data signals Sd sequentially within the timeframe and converts the data signals Sd into driving signals Sdr; the driving signals Sdr are transmitted from one driver unit 21 to the corresponding one group of the grouped functional elements 22 within a sub-timeframe if needed, in which the sub-timeframe is broken down from the timeframe.

In some cases, the switches 23 are integrally built-in the substrate 10. In a detailed description, the switches 23 are not individual components from the substrate 10, for example, the switches 23 can be thin film transistors (TFTs) formed the substrate 10 in an integral manner. In this case, the substrate 10 can be considered as a TFT substrate therefore. In other cases, the driver unit 21 can be a component individual from and arranged on the substrate 10, such as a semiconductor IC.

In some cases, the switch 23 may be integrated with the corresponding functional element 22 while the switch 23 is a semiconductor IC.

In some cases, the switch 23 may include a carrier, and a thin film transistor is formed on the carrier. In this case, the carrier can be a glass substrate or may include glass materials.

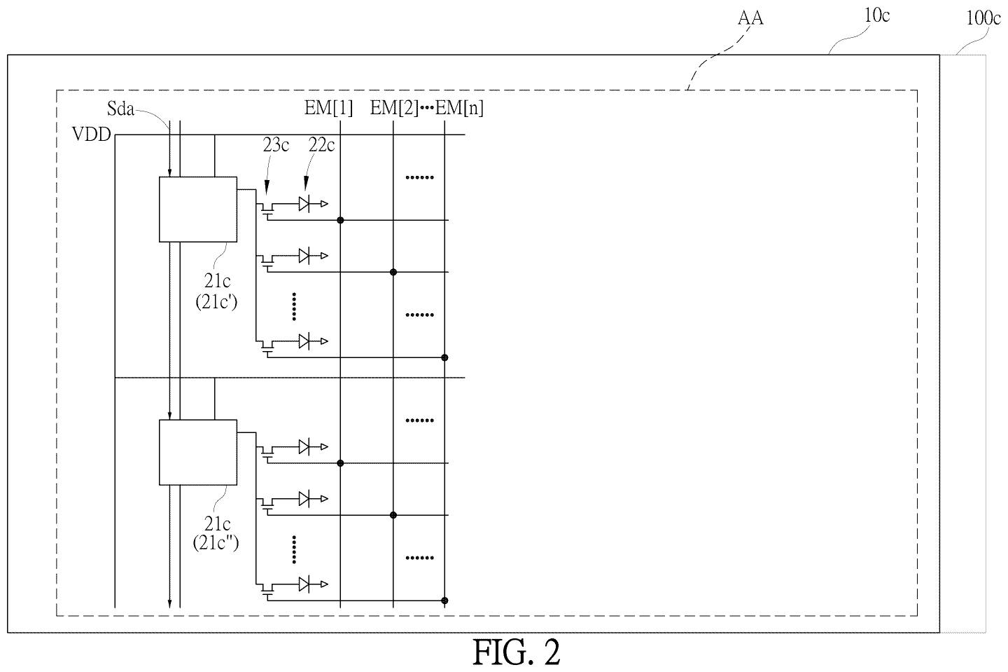

FIG. 2 illustrates another embodiment of this disclosure. The electronic device 100c includes a substrate 10c without the first lines (scan lines), in which the driver units 21c are electrically connected in serial, so that a later one of the driver units 21c″ is driven by a previous one of the driver units 21c′. To be noted, the content of the data signal in the previous one of the driver units 21c′ may be not the same as that in the latter one of the driver units 21c″. However, in other cases, the first lines (scan lines) may be reserved while the driver units 21c are electrically connected in serial.

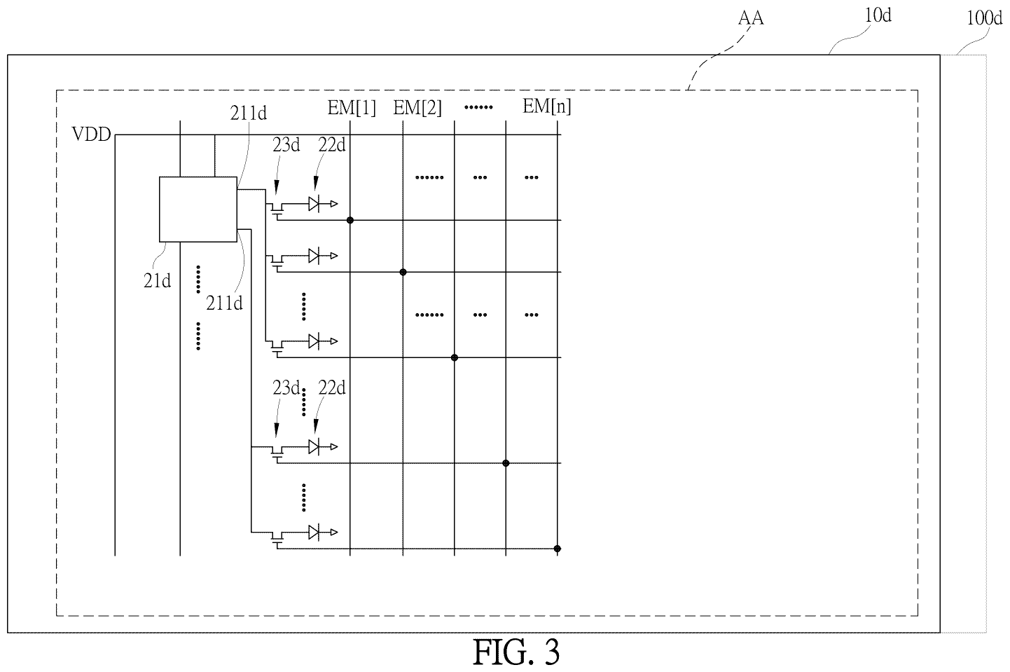

Referring to FIG. 3, at least one of the driver units 21d of the electronic device 100d defines one or more outputs 211d corresponding to ones of the functional elements 22d. In one case, the ones of the functional elements 22d are selected from different groups of the grouped functional elements 22d.

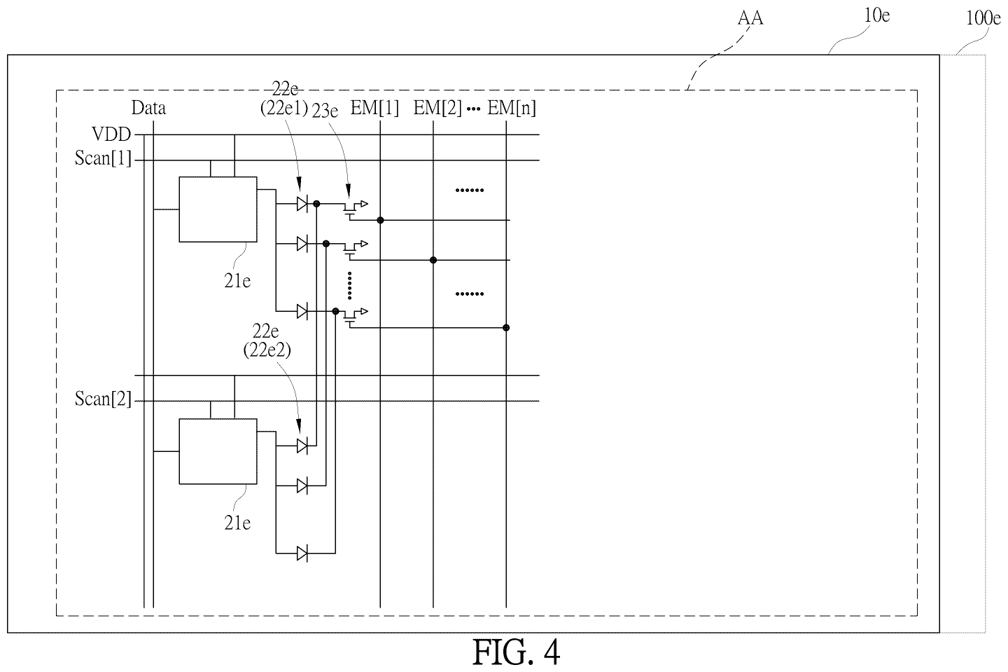

In a case shown by FIG. 4, one of the switches 23e of the electronic device 100e actuates at least two of the functional elements 22e l/22e2. In addition, two groups of the grouped functional elements 22e can also be actuated by the same one group of the grouped switches 23e. In one case, one group of the grouped switches 23e actuates ones of the groups of the grouped functional elements 22e. For example, two groups of the grouped functional elements 22e are actuates by the same one group of the grouped switches 23e.

In the abovementioned embodiments, the substrate 10/10a/10b/10c/10d/10e further defines at least one active area AA and a non-active area other than the at least one active area AA. The driver units 21/21a/21b/21c/21d/21e, the functional elements 22/22a/22b/22c/22d/22e, and the switches 23/23a/23b/23c/23d/23e are arranged within the at least one active area AA. One or ones of the functional elements can be self-emitting elements, such as inorganic light emitters. To be noted, the data signals can be delivered from a system driver coupled with the substrate 10/10a/10b/10c/10d/10e; and the system driver is usually arranged within the non-active area, but not limited to.

In addition, the substrate may further include a plurality of thin-filmed traces formed on the substrate in which the traces are respectively connected to the driver units, the switches, and the functional elements.

Further, the driving signal delivered by the driver unit is current typed, but not limited thereto.

In some cases, the driver unit and functional element are arranged on opposite surfaces of the substrate and the projections of both the driver unit and the functional element perpendicular to the substrate are partially overlapped or fully overlapped. In another cases, the driver units and functional elements are arranged on one surface of the substrate.

In the abovementioned cases, this disclosure is applied on display devices, so the functional elements (ex. the light-emitting elements, LEDs) need to be controlled precisely, and this disclosure can improve the efficiency of the signal propagation and power management thereof. The display device applied with this disclosure also controls the functional elements more precisely and efficiently since the plural functional elements are controlled individually. So, the display device applied with this disclosure has lower power consumption and lower production cost.

This disclosure can be also applied on another type of electronic device such as a sensor panel. In this case, the sensor panel has a plurality of functional elements arranged on a substrate, in which the substrate also has a plurality pixel control units corresponds to the functional elements. In addition, the functional elements can be sensors, for example, X-ray sensors. The pixel control units receive a plurality of sensing signals from the functional elements, and the pixel control units have the capability to convert the received sensing signals into a plurality of readout signals. The substrate also has a plurality of switches coupled with both the pixel control units and the functional elements. The switch is activated by a control signal so as to enable one of the sensing signals from a corresponding functional element to a corresponding pixel control unit. The sensing signals can be transmitted in a sequential manner from the functional elements to the corresponding pixel control units by the enabling of the corresponding switches. In some cases, the switches are integrated within the substrate, but not limited thereto.

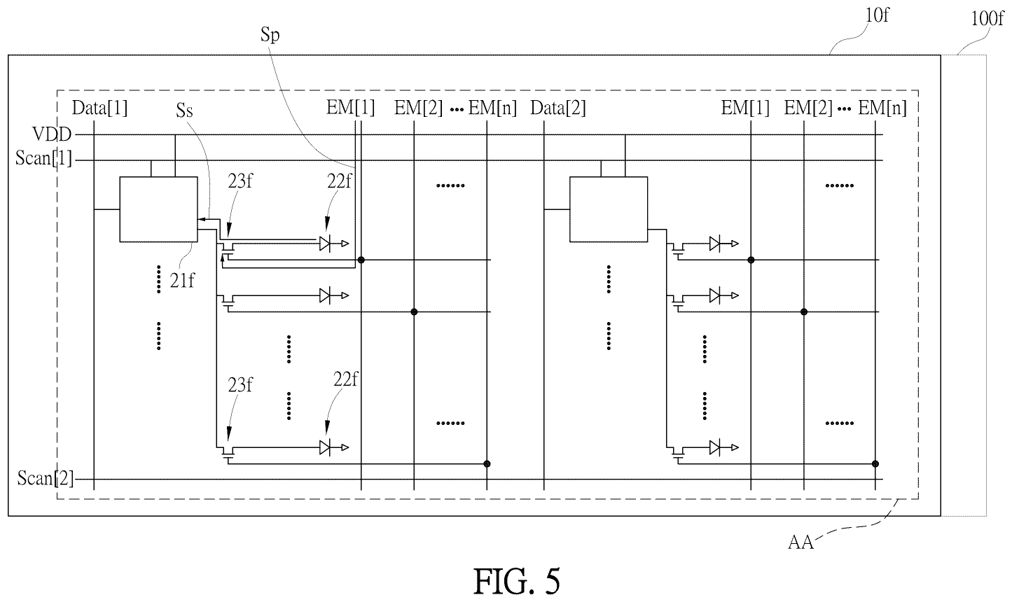

Referring to FIG. 5, an electronic device 100f includes a substrate 10f and having sensing ability is disclosed. The substrate 10f includes a plurality of pixel control units 21f, a plurality of functional elements 22f, and a plurality of switches 23f. In this case, the functional elements 22f can be sensors, ex. X-ray sensors, photo sensor or ultrasonic transducers, and the electronic device can be an X-ray sensor device while the functional elements are X-ray sensors. The pixel control units 21f receive a plurality of sensing Ss signals from the functional elements 22f within a timeframe and convert the sensing signals Ss into a plurality of readout signals Sr. The functional elements 22f are configured to at least one corresponding pixel control unit 21f. The switches 23f are coupled to the pixel control units 21f and the functional elements 22f; the switches 23e are enabled via a corresponding prompt signal Sp to activate one of the sensing signals Ss from a corresponding functional element 22f. The sensing signals Ss are transmitted sequentially from the functional elements 22e to one of the pixel control units 21f by the corresponding switches 23f enabling.

To be noted, the embodiment shown in FIG. 5 has a similar structure of the electronic device referred in FIG. 1A to FIG. 4, the main difference between these embodiments is the transmission route, which can be compared in FIG. 1B and FIG. 5.

In addition, one or ones of the switches can be integrated with a corresponding one of the pixel control units in this embodiment. In some cases, the pixel control unit includes an analog-to-digital converting circuit for converting the sensing signal from an analog type to a digital type. In some cases, the pixel control units and functional elements are arranged on opposite surfaces of the substrate. In some cases, the sensing signal received by the pixel control units is current typed, voltage typed or charge typed.

Accordingly, this disclosure can be applied to electronic device that requires propagating data signal and operating component efficiently, and the type of the electronic device is not limited to the abovementioned display device or sensor. This disclosure can be applied to different types or sizes of electronic devices, from small wearable electronics to large-scale industrial machinery. This disclosure has advantages of power saving and production cost reducing, so this disclosure may become a key technical feature in the future of sustainable electronics design.

What is claimed is:

1. An electronic device comprising:
a substrate including:
a plurality of driver units, wherein one or ones of the driver units receive a plurality of data signals and convert corresponding ones of the data signals into a plurality of driving signals;
a plurality of functional elements driven by corresponding ones of the driver units, and
a plurality of switches coupling to the driver units and the functional elements; wherein one or ones of the switches is enabled via one or ones prompt signal to activate one or ones of the driving signals to a corresponding one or ones of the functional elements; the driving signals are transmitted from one or ones of the driver units to one or ones of the functional elements by the corresponding one or ones of the switches enabling.

2. The electronic device as claimed in claim 1, wherein the substrate further defines a plurality of circuitries, and the circuitries receive the plurality of data signals; wherein one of the driver units, one or ones of the functional elements, and one or ones of the switches are provided in a corresponding one of the circuitries.

3. The electronic device as claimed in claim 1, wherein the driver units receive the data signals sequentially within a timeframe.

4. The electronic device as claimed in claim 3, wherein the driving signals are transmitted from one or ones of the driver units to the corresponding one or ones of the functional elements within a sub-timeframe, wherein the sub-timeframe is broken down from the timeframe.

5. The electronic device as claimed in claim 1, wherein one or ones of the driver units is a component individual from and disposed on the substrate.

6. The electronic device as claimed in claim 1, wherein either or both of at least one of the driver units and the switches is a semiconductor IC.

7. The electronic device as claimed in claim 1, wherein one or ones of the switches is integrated within the substrate or integrated with a corresponding one of the functional elements.

8. The electronic device as claimed in claim 1, wherein one or ones of the switches includes/is a thin film transistor.

9. The electronic device as claimed in claim 1, wherein the substrate further defines at least one active area; wherein one or ones of the driver units, one or ones of the functional elements, and one or ones of the switches are arranged within the at least one active area.

10. The electronic device as claimed in claim 1, wherein the functional elements are grouped, and one or ones group of the functional elements is driven by a corresponding one or ones of the driver units; the switches are grouped, and one or ones groups of the grouped switches relates to corresponding one or ones groups of the grouped functional elements; wherein one or ones of the driver units defines one or more outputs corresponding to one or ones groups of the grouped functional elements.

11. The electronic device as claimed in claim 1, wherein the driver units are electrically connected in serial, and a later one of the driver units is driven by a previous one of the driver units.

12. An electronic device comprising:
a substrate including:
a plurality of pixel control units, wherein one or ones of the pixel control units receive a plurality of sensing signals and convert corresponding ones of the sensing signals into a plurality of readout signals;
a plurality of functional elements configured to corresponding ones of the pixel control units; and
a plurality of switches coupling to the pixel control units and the functional elements; wherein one or ones of the switches is enabled via one or ones of prompt signals to activate one or ones of the sensing signals from a corresponding one or ones of the functional elements; one or ones of the sensing signals are transmitted from one or ones of the functional elements to one or ones of the pixel control units by the corresponding one or ones of the switches enabling.

13. The electronic device as claimed in claim 12, wherein the substrate further defines a plurality of circuitries, and the circuitries receive the sensing signals; wherein one of the pixel control units, one or one of the functional elements, and one or one of the switches are provided in a corresponding one of the circuitries.

14. The electronic device as claimed in claim 12, wherein the pixel control units deliver the readout signals sequentially within a timeframe.

15. The electronic device as claimed in claim 14, wherein the sensing signals are transmitted to one or ones of the pixel control units from the corresponding one or ones of the functional elements within a sub-timeframe, wherein the sub-time frame is broken down from the timeframe.

16. The electronic device as claimed in claim 12, wherein one or ones of the pixel control units is a component individual from and disposed on the substrate.

17. The electronic device as claimed in claim 12, wherein either or both of at least one of the pixel control units and the switches is a semiconductor integrated circuit.

18. The electronic device as claimed in claim 12, wherein one or ones of the switches is integrated within the substrate, integrated with a corresponding one or ones of the functional elements, or integrated with a corresponding one or ones of the pixel control units.

19. The electronic device as claimed in claim 12, wherein one or ones of the switches includes/is a thin film transistor.

20. The electronic device as claimed in claim 12, wherein one or ones of the functional elements is a photo sensor or an ultrasonic transducer.

21. The electronic device as claimed in claim 12, wherein the substrate further defines at least one active area; wherein one or ones of the pixel control units, one or ones of the functional elements, and one or ones of the switches are arranged within the at least one active area.

22. The electronic device as claimed in claim 12, wherein the functional elements are grouped, and the switches are grouped, wherein one or ones groups of the grouped switches corresponds to corresponding one or ones groups the grouped functional elements; wherein one or ones of the pixel control units defines one or more inputs corresponding to one or ones groups of the grouped functional elements.

23. The electronic device as claimed in claim 12, wherein the pixel control units are electrically connected in serial, and a later one of the pixel control units is informed to deliver one of the readout signals by a previous one of the pixel control units.
